(19) United States
(12) Patent Application Publication
(10) Pub. No.: US 2026/0136548 A1
(43) Pub. Date: May 14, 2026

(54) SEMICONDUCTOR DEVICE AND METHOD OF MANUFACTURING A SEMICONDUCTOR DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 19/175,910

(22) Filed: Apr. 10, 2025

(30) Foreign Application Priority Data
Nov. 12, 2024 (KR) 10-2024-0160269

(51) Int. Cl. H10B 41/27; H01L 23/00; H01L 25/065; H10B 41/35; H10B 41/40; H10B 43/27; H10B 43/35; H10B 43/40; H10B 80/00

(52) U.S. Cl. CPC H10B 41/27; H10B 41/40; H10B 43/27; H10B 43/40; H10B 80/00; H10B 41/35; H10B 43/35; H10W 80/312; H10W 80/327; H10W 90/00; H10W 90/792

(57) ABSTRACT

A semiconductor device includes a first gate structure including first conductive layers; a first stack at a level corresponding to the first gate structure; a second gate structure on the first gate structure and on the first stack, the second gate structure including second conductive layers; a second stack at a level corresponding to the second gate structure; and a third gate structure on the second gate structure and on the second stack, the third gate structure including third conductive layers. The semiconductor device also includes first contact vias extending into the first gate structure and respectively connected to the first conductive layers; second contact vias passing through the first stack, extending into the second gate structure, and respectively connected to the second conductive layers; and third contact vias passing through the first and second stacks, extending into the third gate structure, and respectively connected to the third conductive layers.

### CROSS-REFERENCE TO RELATED APPLICATION

The present application claims priority under 35 U.S.C. § 119(a) to Korean Patent Application No. 10-2024-0160269 filed on Nov. 12, 2024, in the Korean Intellectual Property Office, which application is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

The degree of integration of a semiconductor device is mainly determined by an area occupied by a unit memory cell of the semiconductor device. As improvements in the degree of integration of semiconductor devices in which memory cells are formed as a single layer on a substrate reaches a limit, three-dimensional semiconductor devices in which memory cells are stacked on a substrate are being proposed. In addition, various structures and manufacturing methods are being developed to improve operation reliability of the semiconductor devices.

### SUMMARY

According to an embodiment of the present disclosure, a semiconductor device may include a first gate structure including first conductive layers; a first stack at a level corresponding to the first gate structure; a second gate structure on the first gate structure and on the first stack, the second gate structure including second conductive layers; a second stack at a level corresponding to the second gate structure; and a third gate structure on the second gate structure and on the second stack, the third gate structure including third conductive layers. The semiconductor device may also include first contact vias extending into the first gate structure and respectively connected to the first conductive layers; second contact vias passing through the first stack, extending into the second gate structure, and respectively connected to the second conductive layers; and third contact vias passing through the first and second stacks, extending into the third gate structure, and respectively connected to the third conductive layers.

According to an embodiment of the present disclosure, a semiconductor device may include a substrate including a first region, a second region surrounding the first region, and a third region surrounding the second region. The semiconductor device may also include a first gate structure over the substrate in the third region, the first gate structure including first conductive layers; a first stack in the first region and in the second region, the first stack at a level corresponding to the first gate structure; a second gate structure on the first gate structure and on the first stack in the second region and in the third region, the second gate structure including second conductive layers; a second stack in the first region at a level corresponding to the second gate structure,; and a third gate structure on the second gate structure and on the third gate structure in the first region, in the second region, and in the third region, the third gate structure including third conductive layers. The semiconductor device may further include first contact vias extending into the first gate structure in the third region and respectively connected to the first conductive layers; second contact vias passing through the first stack in the second region and extending into the second gate structure, the second contact vias respectively connected to the second conductive layers; and third contact vias passing through the first and second stacks in the first region and extending into the third gate structure, the third contact vias respectively connected to the third conductive layers.

### BRIEF DESCRIPTION OF THE DRAWINGS

FIG. 1 is a drawing illustrating a semiconductor device according to an embodiment of the present disclosure.

FIGS. 2A to 2D are drawings illustrating a semiconductor device according to an embodiment of the present disclosure.

FIGS. 3A to 3D are drawings illustrating a semiconductor device according to an embodiment of the present disclosure.

FIG. 4 is a flowchart illustrating a method of manufacturing a semiconductor device according to an embodiment of the present disclosure.

FIGS. 5, 6A, 6B, 7A to 7D, 8A to 8D, 9, 10, 11A to 11C, 12A, 12B, 13A to 13C, and 14 are drawings illustrating a method of manufacturing a semiconductor device according to an embodiment of the present disclosure.

### DETAILED DESCRIPTION

An embodiment of the present disclosure is directed to a semiconductor device and a method of manufacturing the semiconductor device having a stable structure and an improved operating characteristic.

According to the present technology, a semiconductor device may have a stable structure and improved reliability.

Hereinafter, some embodiments according to the technical spirit of the present disclosure are described with reference to the accompanying drawings.

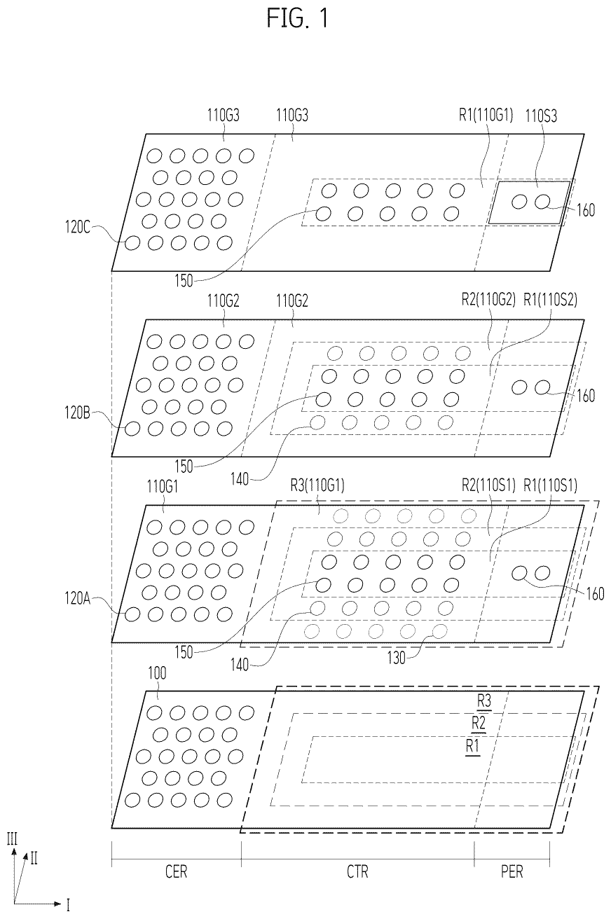

FIG. 1 is a drawing illustrating a semiconductor device according to an embodiment of the present disclosure.

Referring to FIG. 1, the semiconductor device may include a substrate 100, a first stack 110S1, a second stack 110S2, a third stack 110S3, a first gate structure 110G1, a second gate structure 110G2, a third gate structure 110G3, first sub-channel structures 120A, second sub-channel structures 120B, third sub-channel structures 120C, first contact vias 130, second contact vias 140, third contact vias 150, and contact plugs 160.

The substrate 100 may include a cell region CER, a contact region CTR, and a peripheral circuit region PER. The cell region CER may be spaced apart from the peripheral circuit region PER in a first direction I. The contact region CTR may be between the cell region CER and the peripheral circuit region PER. The cell region CER may be a region where memory cells are located. The contact region CTR may be a region where contact vias 130, 140, and 150 respectively connected to first/second/third conductive layers of first/second/third gate structures 110G1, 110G2, and 110G3 are located. The peripheral circuit region PER may be a region where the contact plugs 160 connected to the peripheral circuit are located.

The substrate 100 may include a first region R1, a second region R2, and a third region R3. The first region R1 may extend in the first direction I. For example, the first region R1 may extend from the contact region CTR to the peripheral circuit region PER. The second region R2 may surround the first region R1. For example, the second region R2 may surround the first region R1 and extend from the contact region CTR to the peripheral circuit region PER. The third region R3 may surround the second region R2. For example, the third region R3 may surround the second region R2 and extend from the contact region CTR to the peripheral circuit region PER.

The first gate structure 110G1 may be over the substrate 100. For example, the first gate structure 110G1 may extend from the cell region CER to the peripheral circuit region PER. In addition, the first gate structure 110G1 may be in the third region R3.

The first stack 110S1 may be over the substrate 100. For example, the first stack 110S1 may extend from the contact region CTR to the peripheral circuit region PER. In addition, the first stack 110S1 may be in the first region R1 and the second region R2. The first stack 110S1 may be at a level corresponding to the first gate structure 110G1.

The second gate structure 110G2 may be on the first stack 110S1 and the first gate structure 110G1. The second gate structure 110G2 may overlap the first gate structure 110G1 in the cell region CER. In addition, the second gate structure 110G2 may be in the second region R2 and the third region R3. In this case, the second gate structure 110G2 may overlap the first stack 110S1 in the second region R2. For example, the second gate structure 110G2 may overlap the first stack 110S1 in the contact region CTR.

The second stack 110S2 may be on the first stack 110S1. The second stack 110S2 may be at a level corresponding to the second gate structure 110G2. The second stack 110S2 may be in the first region R1. In this case, the second stack 110S2 may overlap the first stack 110S1 in the first region R1. For example, the second stack 110S2 may overlap the first stack 110S1 in the peripheral circuit region PER.

Meanwhile, in a second direction II crossing the first direction I, the first stack 110S1 and the second stack 110S2 may have different widths. For example, in the second direction II, the first stack 110S1 may have a width greater than a width of the second stack 110S2. Through this, in a process of manufacturing the semiconductor device, a region for forming the second contact vias 140 connected to the second gate structure 110G2 by passing through the first stack 110S1 may be secured.

The third gate structure 110G3 may be on the second stack 110S2 and the second gate structure 110G2. The third gate structure 110G3 may overlap the first gate structure 110G1 and the second gate structure 110G2 in the cell region CER. In addition, the third gate structure 110G3 may be in the first region R1, the second region R2, and the third region R3. In this case, the third gate structure 110G3 may overlap the first stack 110S1 and the second stack 110S2 in the first region R1. For example, the third gate structure 110G3 may overlap the first stack 110S1 and the second stack 110S2 in the contact region CTR.

The third stack 110S3 may be on the second stack 110S2. The third stack 110S3 may be at a level corresponding to the third gate structure 110G3. The third stack 110S3 may be in the first region R1. In this case, the third stack 110S3 may overlap the first stack 110S1 and the second stack 110S2 in the first region R1. For example, the third stack 110S3 may overlap the first stack 110S1 and the second stack 110S2 in the peripheral circuit region PER.

Meanwhile, in the second direction II, the second stack 110S2 and the third stack 110S3 may have different widths. For example, in the second direction II, the second stack 110S2 may have a width greater than a width of the third stack 110S3. Through this, in the process of manufacturing the semiconductor device, a region for forming the third contact vias 150 connected to the third gate structure 110G3 by passing through the first stack 110S1 and the second stack 110S2 may be secured.

The first sub-channel structures 120A may be over the substrate 100. For example, the first sub-channel structures 120A may be in the cell region CER. The first sub-channel structures 120A may pass through the first gate structure 110G1.

The second sub-channel structures 120B may be on the first sub-channel structures 120A. The second sub-channel structures 120B may pass through the second gate structure 110G2 and may be connected to the first sub-channel structures 120A.

The third sub-channel structures 120C may be on the second sub-channel structures 120B. The third sub-channel structures 120C may pass through the third gate structure 110G3 and may be connected to the second sub-channel structures 120B.

The first contact vias 130 may be in the contact region CTR. In addition, the first contact vias 130 may be in the third region R3. The first contact vias 130 may be respectively connected to first conductive layers of the first gate structure 110G1.

The second contact vias 140 may be in the contact region CTR. In addition, the second contact vias 140 may be in the second region R2. The second contact vias 140 may be respectively connected to second conductive layers of the second gate structure 110G2 by passing through the first stack 110S1.

The third contact vias 150 may be in the contact region CTR. In addition, the third contact vias 150 may be in the first region R1. The third contact vias 150 may be respectively connected to third conductive layers of the third gate structure 110G3 by passing through the first stack 110S1 and the second stack 110S2.

The contact plugs 160 may be in the peripheral circuit region PER. In addition, the contact plugs 160 may be in the first region R1. The contact plugs 160 may be electrically connected to the peripheral circuit by passing through the first stack 110S1, the second stack 110S2, and the third stack 110S3.

According to the structure described above, the substrate 100 may include the first region R1, the second region R2 surrounding the first region R1, and the third region R3 surrounding the second region R2. The first contact vias 130 may be in the third region R3, the second contact vias 140 may be in the second region R2, and the third contact vias 150 may be in the first region R1. In other words, the contact vias 130, 140, and 150 connected to the respective gate structures 110G1, 110G2, and 110G3 may be in different regions so as not to overlap each other. That is, by distributing and locating the contact vias 130, 140, and 150 in limited non-overlapping regions, the degree of integration of the semiconductor device may be improved.

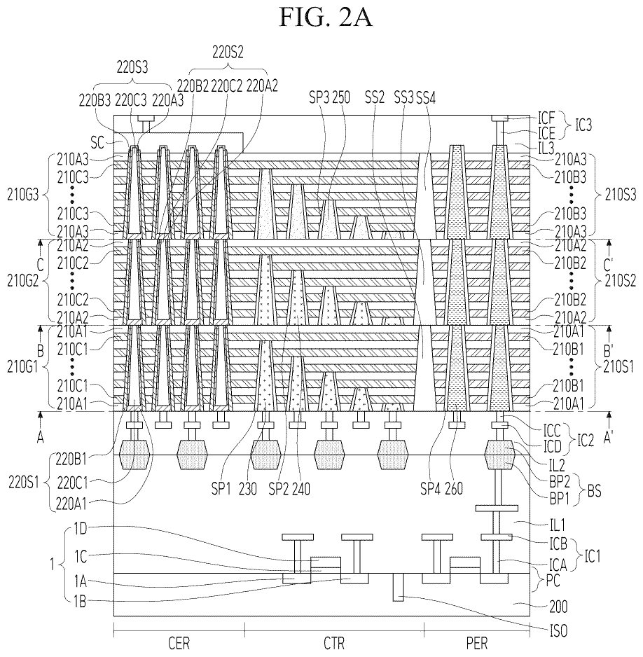

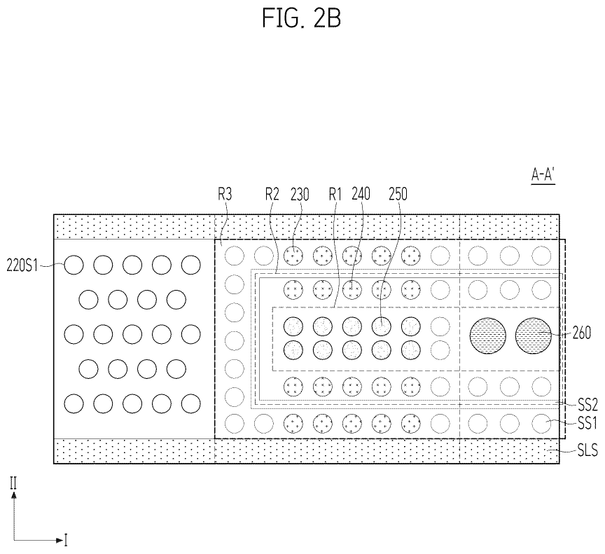

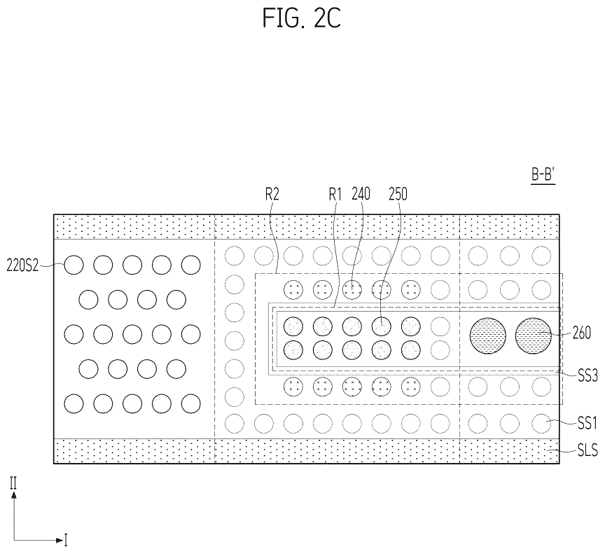

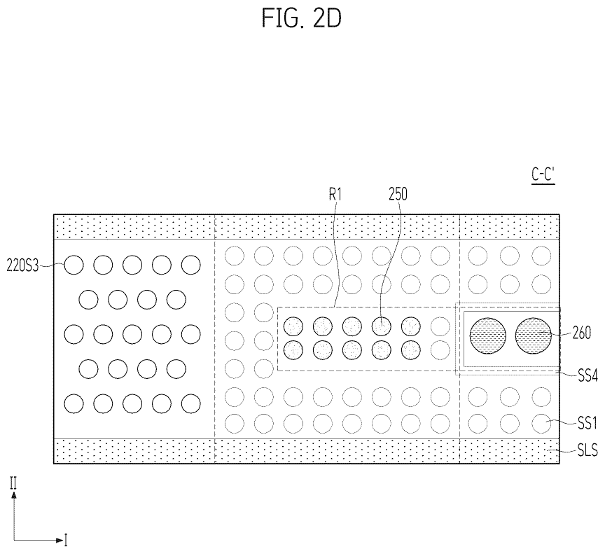

FIGS. 2A to 2D are drawings illustrating a semiconductor device according to an embodiment of the present disclosure. FIG. 2A is a cross-sectional view, FIG. 2B is a plan view at A-A′ level of FIG. 2A, FIG. 2C is a plan view at B-B′ level of FIG. 2A, and FIG. 2D is a plan view at C-C′ level of FIG. 2A. Hereinafter, content already described above is not repeated.

For reference, FIG. 2A is a drawing that combines cross-sections of different locations for convenience of description. For example, FIG. 2A is a drawing that combines a cross-section illustrating that first conductive layers 210C1 of a first gate structure 210G1 and first contact vias 230 are respectively connected, a cross-section illustrating that second conductive layers 210C2 of a second gate structure 210G2 and second contact vias 240 are respectively connected, and a cross-section illustrating that third conductive layers 210C3 of a third gate structure 210G3 and third contact vias 250 are respectively connected.

Referring to FIGS. 2A to 2D, the semiconductor device may include a substrate 200, a first stack 210S1, a second stack 210S2, a third stack 210S3, the first gate structure 210G1, the second gate structure 210G2, the third gate structure 210G3, first sub-channel structures 220S1, second sub-channel structures 220S2, third sub-channel structures 220S3, first contact vias 230, second contact vias 240, third contact vias 250, and contact plugs 260. The semiconductor device may further include a peripheral circuit PC, a first interconnection structure IC1, a second interconnection structure IC2, a third interconnection structure IC3, a first interlayer insulating layer IL1, a second interlayer insulating layer IL2, a third interlayer insulating layer IL3, first insulating spacers SP1, second insulating spacers SP2, third insulating spacers SP3, fourth insulating spacers SP4, first supports SS1, second support SS2, third support SS3, fourth support S44, a source structure SC, a slit structure SLS, and a bonding structure BS.

The substrate 200 may include a cell region CER, a contact region CTR, and a peripheral circuit region PER. The substrate 200 may also include a first region R1, a second region R2, and a third region R3. The first region R1 may extend in a first direction I. The second region R2 may surround the first region R1. The third region R3 may surround the second region R2.

The peripheral circuit PC may be on the substrate 200. The peripheral circuit PC may include a transistor 1, a capacitor, and the like. The transistor 1 may include junctions 1A and 1B, a gate electrode 1D, and a gate insulating layer 1C. Here, the gate insulating layer 1C may be between the gate electrode 1D and the substrate 200. An element isolation layer ISO may be in the substrate 200, and an active region may be defined by the element isolation layer ISO, and the transistor 1 may be in the active region.

The first interconnection structure IC1 may be on the peripheral circuit PC. The first interconnection structure IC1 may be in the first interlayer insulating layer IL1. Here, the first interlayer insulating layer IL1 may be on the substrate 200. The first interconnection structure IC1 may include first vias ICA and first lines ICB.

The first interconnection structure IC1 may be connected to the peripheral circuit PC. For example, at least one of the first vias ICA may be connected to the transistor 1. At least one of the first vias ICA may interconnect the first lines ICB. The first lines ICB may interconnect the first vias ICA. The first interconnection structure IC1 may include a conductive material, such as tungsten. The first interlayer insulating layer IL may include an insulating material, such as an oxide.

The bonding structures BS may be on the first interconnection structure IC1. The bonding structure BS may include a first bonding pad BP1 and a second bonding pad BP2. The first bonding pad BP1 may be in the first interlayer insulating layer IL1. The second bonding pad BP2 may be in the second interlayer insulating layer IL2. Here, the second interlayer insulating layer IL2 may be on the first interlayer insulating layer IL1.

The second interconnection structure IC2 may be on the bonding structure BS. The second interconnection structure IC2 may be in the second interlayer insulating layer IL2. The second interconnection structure IC2 may include second vias ICC and second lines ICD.

The first gate structure 210G1 may be over the substrate 200. The first gate structure 110G1 may extend from the cell region CER to the peripheral circuit region PER. In addition, the first gate structure 210G1 may be in the third region R3. The first gate structure 210G1 may include first insulating layers 210A1 and the first conductive layers 210C1 alternately stacked with each other.

The first stack 210S1 may be over the substrate 200. The first stack 210S1 may extend from the contact region CTR to the peripheral circuit region PER. In addition, the first stack 210S1 may be in the first region R1 and the second region R2. The first stack 210S1 may be at a level corresponding to the first gate structure 210G1. The first stack 210S1 may include first insulating layers 210A1 and second insulating layers 210B1 alternately stacked with each other.

The second gate structure 210G2 may be on the first gate structure 210G1. In addition, the second gate structure 210G2 may be in the second region R2 and the third region R3. The second gate structure 210G2 may include third insulating layers 210A2 and the second conductive layers 210C2 alternately stacked with each other.

The second stack 210S2 may be on the first stack 210S1. The second stack 210S2 may be at a level corresponding to the second gate structure 210G2. The second stack 210S2 may be in the first region R1. The second stack 210S2 may include third insulating layers 210A2 and fourth insulating layers 210B2 alternately stacked with each other.

The third gate structure 210G3 may be on the second gate structure 210G2. In addition, the third gate structure 210G3 may be in the first region R1, the second region R2, and the third region R3. The third gate structure 210G3 may include fifth insulating layers 210A3 and the third conductive layers 210C3 alternately stacked with each other.

The third stack 210S3 may be on the second stack 210S2. The third stack 210S3 may be at a level corresponding to the third gate structure 110G3. The third stack 210S3 may be in the first region R1. The third stack 210S3 may include fifth insulating layers 210A3 and sixth insulating layers 210B3 alternately stacked with each other.

The first, second, and third conductive layers 210C1, 210C2, and 210C3 may be gate lines, such as source selection lines, word lines, and drain selection lines. A source selection transistor, a memory cell, or a drain selection transistor may be in a region where the first, second, and third sub-channel structures 220S1, 220S2, and 220S3 and the first, second, and third conductive layers 210C1, 210C2, and 210C3 cross. For example, at least one source selection transistor, a plurality of memory cells, and at least one drain selection transistor stacked along the first, second, and third sub-channel structures 220S1, 220S2, and 220S3 may configure one memory string. The first, second, and third conductive layers 210C1, 210C2, and 210C3 may include a conductive material, such as tungsten, molybdenum, or polysilicon.

The first sub-channel structures 220S1 may extend through the first gate structure 210G1. The first sub-channel structures 220S1 may include a first sub-channel layer 220A1, a first sub-memory layer 220B1 surrounding the first sub-channel layer 220A1, and a first sub-insulating core 220C1 in the first sub-channel layer 220A1.

The second sub-channel structures 220S2 may be on the first sub-channel structures 210S1. The second sub-channel structures 220S2 may extend through the second gate structure 210G2 and may be connected to the first sub-channel structures 220S1. The second sub-channel structures 220S2 may include a second sub-channel layer 220A2, a second sub-memory layer 220B2 surrounding the second sub-channel layer 220A2, and a second sub-insulating core 220C2 in the second sub-channel layer 220A2.

The third sub-channel structures 220S3 may be on the second sub-channel structures 220S2. The third sub-channel structures 220S3 may extend through the third gate structure 210G3 and may be connected to the second sub-channel structures 220S2. The third sub-channel structures 210S3 may include a third sub-channel layer 220A3, a third sub-memory layer 220B3 surrounding the third sub-channel layer 220A3, and a third sub-insulating core 220C3 in the third sub-channel layer 220A3.

The source structure SC may be on the third sub-channel structures 220S3. Here, the third sub-channel structures 220S3 may extend through the third gate structure 210G3 and into the source structure SC. The source structure SC may be a single layer or multiple layers. The source structure SC may include a semiconductor material, such as polysilicon.

The first contact vias 230 may be in the contact region CTR. In addition, the first contact vias 230 may be in the third region R3. The first contact vias 130 may extend into the first gate structure 210G1 and may be respectively connected to the first conductive layers 210C1. Here, a sidewall of the first contact vias 230 may be surrounded by first insulating spacers SP1. The first contact vias 230 may include a conductive material, such as tungsten, and the first insulating spacers SP1 may include an insulating material, such as an oxide.

The second contact vias 240 may be in the contact region CTR. In addition, the second contact vias 240 may be in the second region R2. The second contact vias 240 may extend through the second gate structure 210G2 and may be respectively connected to the second conductive layers 210C2. Here, a sidewall of the second contact vias 240 may be surrounded by the second insulating spacers SP2. The second contact vias 240 may include a conductive material, such as tungsten, and the second insulating spacers SP2 may include an insulating material, such as an oxide.

The third contact vias 250 may be in the contact region CTR. In addition, the third contact vias 250 may be in the first region R1. The third contact vias 250 may extend through the third gate structure 210G3 and may be respectively connected to the third conductive layers 210C3. Here, a sidewall of the third contact vias 250 may be surrounded by the third insulating spacers SP3. The third contact vias 250 may include a conductive material, such as tungsten, and the third insulating spacers SP3 may include an insulating material, such as an oxide.

The contact plugs 260 may be in the peripheral circuit region PER. In addition, the contact plugs 260 may be in the first region R1. The contact plugs 260 may be electrically connected to the peripheral circuit PC by passing through the first stack 210S1, the second stack 210S2, and the third stack 210S3. For example, the contact plug 260 may be electrically connected to the peripheral circuit PC through the second interconnection structure IC2, the bonding structure BS, and the first interconnection structure IC1 by passing through the first stack 210S1, the second stack 210S2, and the third stack 210S3. The contact plugs 260 may include a conductive material, such as tungsten.

The third interconnection structure IC3 may be over the third gate structure 210G3 and the third stack 210S3. The third interconnection structure IC3 may be in the third interlayer insulating layer IL3. Here, the third interlayer insulating layer IL3 may be on the third gate structure 210G3 and the third stack 210S3. The third interconnection structure IC3 may include third vias ICE and third lines ICF.

The first supports SS1 may be in the contact region CTR and the peripheral circuit region PER. The first supports SS1 may extend through the first gate structure 210G1.

In the first direction I, second support SS2 may extend from the contact region CTR to the peripheral circuit region PER. In addition, the second support SS2 may extend between the first gate structure 210G1 and the first stack 210S1. The second support SS2 may define a region where the first stack 210S1 remains in the process of manufacturing the semiconductor device, and it may be located to surround the first stack 210S1. For example, the second support SS2 may be located to surround the first stack 210S1 in the first and second regions R1 and R2. In this case, the first/second regions R1 and R2 and the third region R3 may be distinguished.

In the first direction I, third support SS3 may extend from the contact region CTR to the peripheral circuit region PER. The third support SS3 may extend between the second gate structure 210G2 and the second stack 210S2. The third support SS3 may be located to surround the second stack 210S2. For example, the third support SS3 may be located to surround the second stack 210S2 in the first region R1. In this case, the first region R1 and the second/third regions R2 and R3 may be distinguished.

The fourth support SS4 may be in the peripheral circuit region PER. The fourth support SS4 may extend between the third gate structure 210G3 and the third stack 210S3. The fourth support SS4 may be located to surround the third stack 210S3. For example, the fourth support SS4 may be located to surround the third stack 210S2 in the first region R1. The first, second, third, and fourth supports SS1, SS2, SS3, and SS4 may include an insulating material, such as an oxide.

The slit structure SLS may extend in the first direction I. For example, the slit structure SLS may extend from the cell region CER to the peripheral circuit region PER. The slit structure SLS may include at least one of an insulating material, a conductive material, or a semiconductor material.

According to the structure described above, the substrate 200 may include the first region R1, the second region R2 surrounding the first region R1, and the third region R3 surrounding the second region R2. The first contact vias 230 respectively connected to the first conductive layers 210C1 of the first gate structure 210G1 may be in the third region R3. The second contact vias 240 respectively connected to the second conductive layers 210C2 of the second gate structure 210G2 may be in the second region R2. The third contact vias 250 respectively connected to the third conductive layers 210C3 of the third gate structure 210G3 may be in the first region R1. In other words, the first, second, and third contact vias 230, 240, and 250 may be in different regions, and the degree of integration of the semiconductor device may be improved by distributing and locating the contact vias 230, 240, and 250 in a limited region.

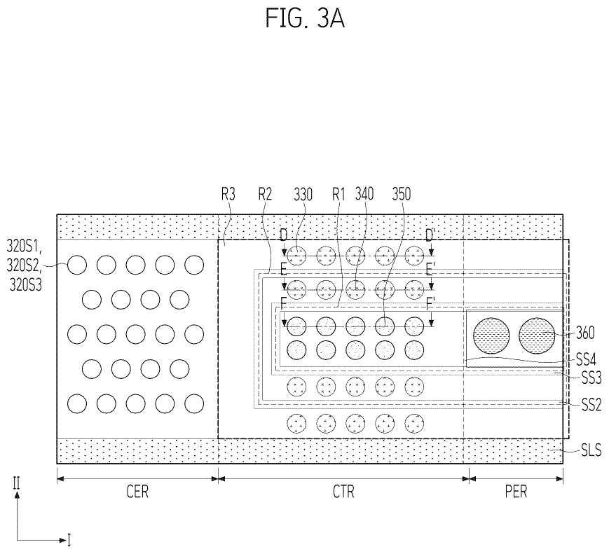

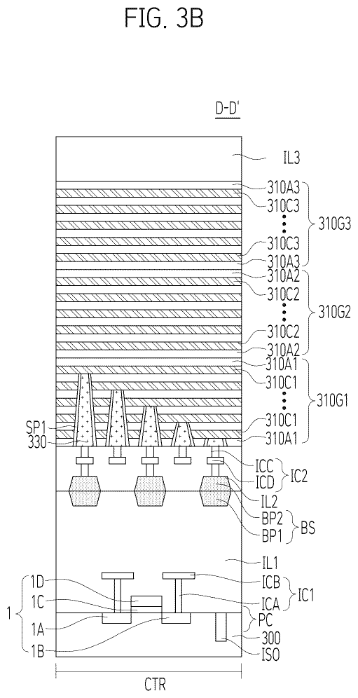

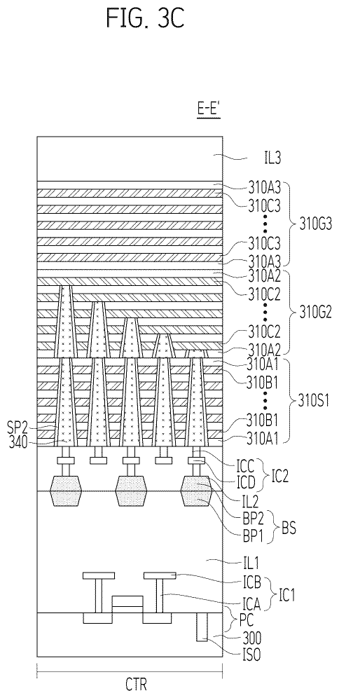

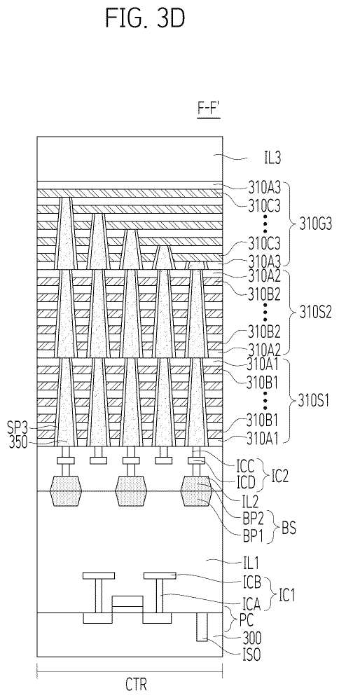

FIGS. 3A to 3D are drawings illustrating a semiconductor device according to an embodiment of the present disclosure. FIG. 3A is a plan view, FIG. 3B is a cross-sectional view taken along line D-D′ of FIG. 3A, FIG. 3C is a cross-sectional view taken along line E-E′ of FIG. 3A, and FIG. 3D is a cross-sectional view taken along line F-F′ of FIG. 3A. Hereinafter, content already described above is not repeated.

Referring to FIGS. 3A to 3D, the semiconductor device may include a substrate 300, a first stack 310S1, a second stack 310S2, a first gate structure 310G1, a second gate structure 310G2, a third gate structure 310G3, first sub-channel structures 320S1, second sub-channel structures 320S2, third sub-channel structures 320S3, first contact vias 330, second contact vias 340, third contact vias 350, contact plugs 360, a slit structure SLS, and a fourth support SS4. The semiconductor device may further include a peripheral circuit PC, a first interconnection structure IC1, a second interconnection structure IC2, a first interlayer insulating layer IL1, a second interlayer insulating layer IL2, a third interlayer insulating layer IL3, first insulating spacers SP1, second insulating spacers SP2, third insulating spacers SP3, and a bonding structure BS.

For reference, the substrate 300, the first stack 310S1, the second stack 310S2, the first gate structure 310G1, the second gate structure 310G2, the third gate structure 310G3, the first contact vias 330, the second contact vias 340, the third contact vias 350, the contact plugs 360, the slit structure SLS, the fourth support SS4, the peripheral circuit PC, the first interconnection structure IC1, the second interconnection structure IC2, the first interlayer insulating layer IL1, the second interlayer insulating layer IL2, the third interlayer insulating layer IL3, the first insulating spacers SP1, the second insulating spacers SP2, the third insulating spacers SP3, and the bonding structure BS of FIGS. 3A to 3D may correspond to the substrate 200, the first stack 210S1, the second stack 210S2, the first gate structure 210G1, the second gate structure 210G2, the third gate structure 210G3, the first sub-channel structures 220S1, the second sub-channel structures 220S2, the third sub-channel structures 220S3, the first contact vias 230, the second contact vias 240, the third contact vias 250, the contact plugs 260, the slit structure SLS, the fourth support SS4, the peripheral circuit PC, the first interconnection structure IC1, the second interconnection structure IC2, the first interlayer insulating layer IL1, the second interlayer insulating layer IL2, the third interlayer insulating layer IL3, the first insulating spacers SP1, the second insulating spacers SP2, the third insulating spacers SP3, and the bonding structure BS.

The first, second, and third contact vias 330, 340, and 350 may be in different regions. For example, the first contact vias 330 may be in the third region R3, the second contact vias 340 may be in the second region R2, and the third contact vias 350 may be in the first region R1. The third gate structure 310G3 may be in the third region R3; the first stack 310S1 and the second gate structure 310G2 may be in the second region R2; and the first stack 310S1, the second stack 310S2, and the third gate structure 310G3 may be in the first region R1.

In this case, the first contact vias 330 may extend into the first gate structure 310G1 and may be respectively connected to first conductive layers 310C1. The second contact vias 340 may extend into the second gate structure 310G2 by passing through the first stack 310S1, and they may be respectively connected to second conductive layers 310C2. The third contact vias 350 may extend into the third gate structure 310G3 by passing through the first stack 310S1 and the second stack 310S2, and they may be respectively connected to third conductive layers 310C3. In other words, by distributing and locating the first, second, and third contact vias 330, 340, and 350, the degree of integration of the semiconductor device may be improved in a limited region.

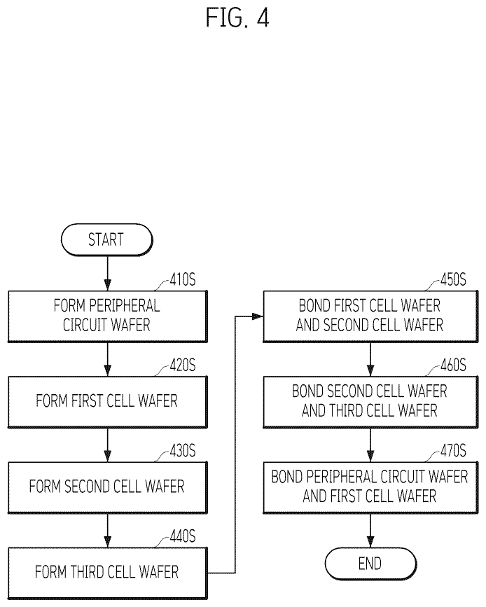

FIG. 4 is a flowchart illustrating a method of manufacturing a semiconductor device according to an embodiment of the present disclosure. Hereinafter, content already described above is not repeated.

Referring to FIG. 4, a peripheral circuit wafer may be formed (410S). For example, a peripheral circuit wafer including a peripheral circuit may be formed. The peripheral circuit wafer may further include first bonding pads.

Subsequently, a first cell wafer may be formed (420S). For example, a first cell wafer including a first stack, first connection vias passing through the first stack, a first gate structure including first conductive layers, and first contact vias extending through the first gate structure and respectively connected to the first conductive layers may be formed. The first cell wafer may further include a first through plug passing through the first stack. The first cell wafer may further include second bonding pads. Here, the first connection vias may be formed in consideration of a region where second connection vias and second contact vias of a second cell wafer are to be formed.

Subsequently, the second cell wafer may be formed (430S). For example, a second cell wafer including a second stack, the second connection vias passing through the second stack, a second gate structure including second conductive layers, and the second contact vias extending through the second gate structure and respectively connected to the second conductive layers may be formed. The second cell wafer may further include a first through plug passing through the second stack. Here, the second connection vias may be formed in consideration of a region where third contact vias of a third cell wafer are to be formed.

Subsequently, the third cell wafer may be formed (440S). For example, a third cell wafer including a third stack, a third gate structure including third conductive layers, and the third contact vias extending through the third gate structure and respectively connected to the third conductive layers may be formed. The third cell wafer may further include a first through plug passing through the third stack.

Subsequently, the first cell wafer and the second cell wafer may be bonded (450S). For example, the first cell wafer and the second cell wafer may be bonded together so that the first connection vias of the first cell wafer and the second connection vias of the second cell wafer are interconnected. Here, the first cell wafer and the second cell wafer may be bonded so that the first connection vias and the second contact vias are interconnected.

Subsequently, the second cell wafer and the third cell wafer may be bonded (460S). For example, the second cell wafer and the third cell wafer may be bonded together so that the second connection vias of the second cell wafer and the third contact vias of the third cell wafer are interconnected. Accordingly, the third contact vias may be connected to the first connection vias through the second connection vias.

Subsequently, the first cell wafer and the peripheral circuit wafer may be bonded (470S). For example, the peripheral circuit wafer and the first cell wafer may be bonded together so that the first bonding pads of the peripheral circuit wafer and the second bonding pads of the first cell wafer are interconnected.

The order in which the first, second, and third cell wafers and the peripheral circuit wafer are formed is not limited to the order described above. For example, the peripheral circuit wafer may be formed after the first, second, and third cell wafers are formed. In addition, the order in which the first, second, and third cell wafers and the peripheral circuit wafer are bonded is not limited to the order described above. For example, the first cell wafer and the second cell wafer may be bonded after the first cell wafer and the peripheral circuit wafer are bonded.

When structures included in the first, second, and third cell wafers are to be formed in one cell wafer without forming the first, second, and third cell wafers separately, bending may occur in a gate structure and/or a stack configuring the cell wafer. This problem may be aggravated when a height of the gate structure and/or the stack are/is increased to improve the degree of integration of the semiconductor device.

However, according to an embodiment of the present disclosure, the first, second, and third cell wafers and the peripheral circuit wafer may be formed separately. A height of the first, second, and third gate structures and/or the first, second, and third stacks may be formed relatively small, and bending of the first, second, and third gate structures and/or the first, second, and third stacks may be prevented or reduced. In addition, the first, second, and third gate structures may be interconnected; a high height of a semiconductor device may be formed by interconnecting the first, second, and third stacks; and the degree of integration of the semiconductor device may be improved.

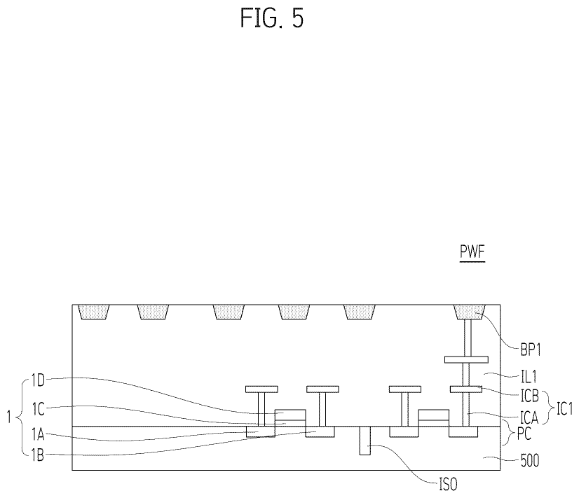

FIGS. 5, 6A, 6B, 7A to 7D, 8D to 8D, 9, 10, 11A to 11C, 12A, 12B, 13A to 13C, and 14 are drawings illustrating a method of manufacturing a semiconductor device according to an embodiment of the present disclosure.

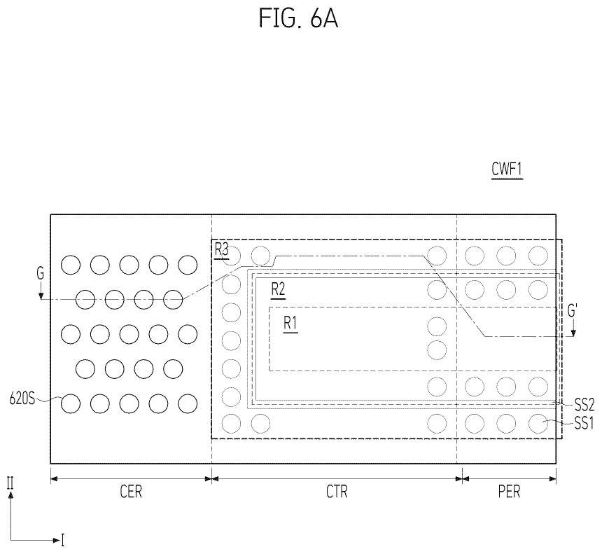

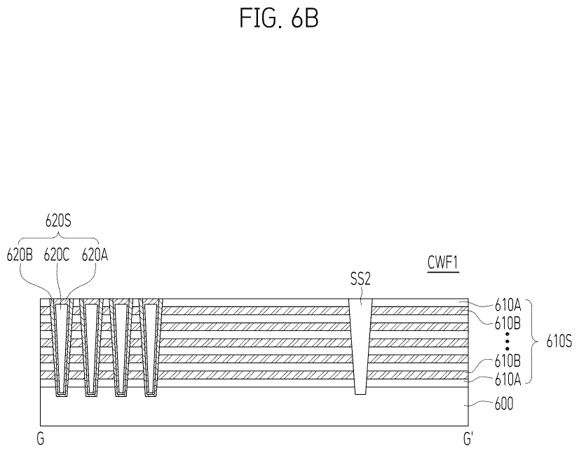

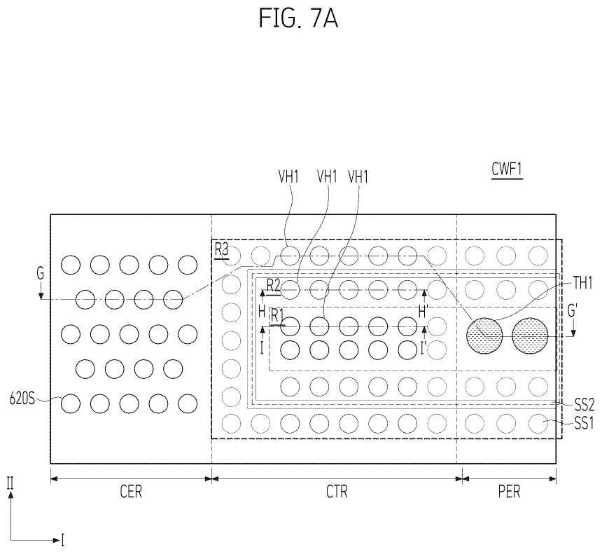

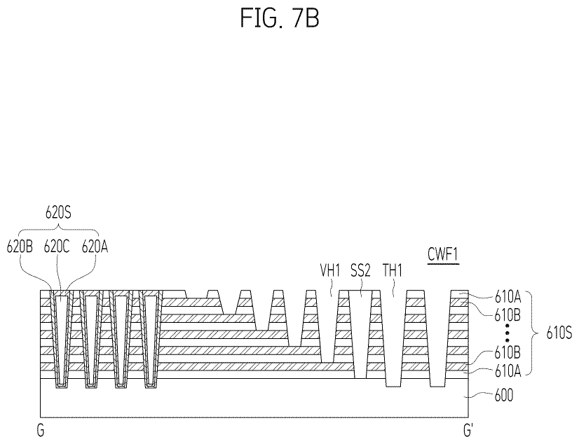

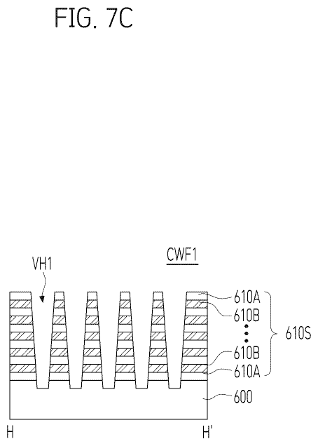

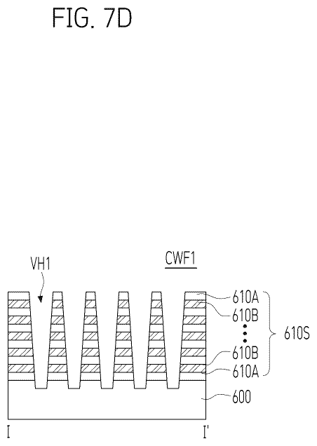

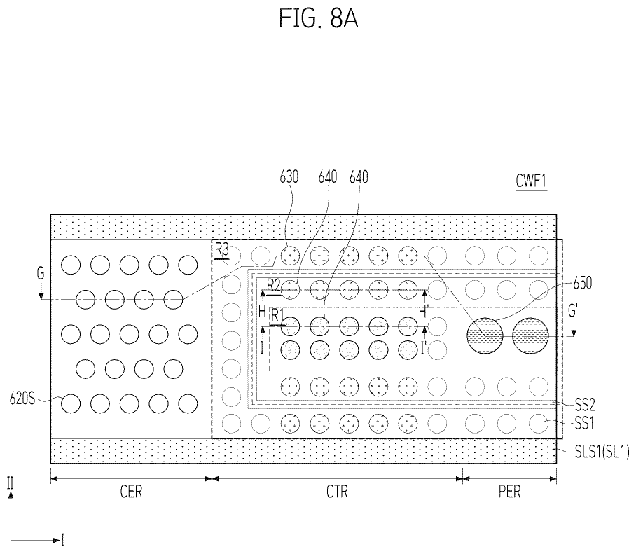

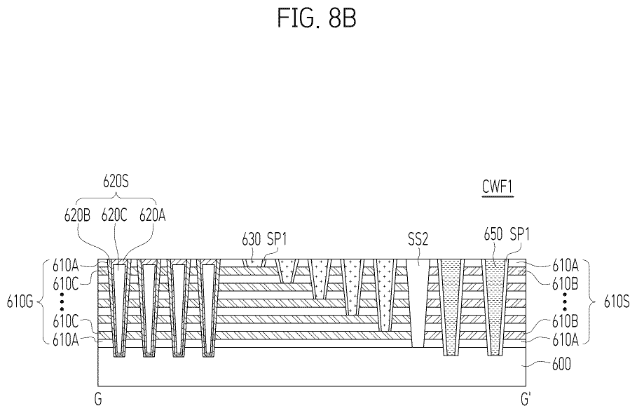

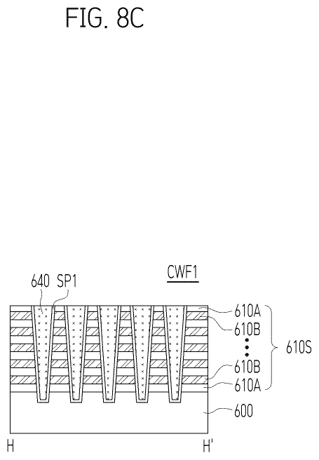

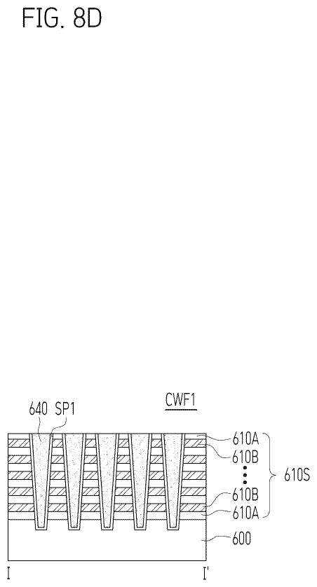

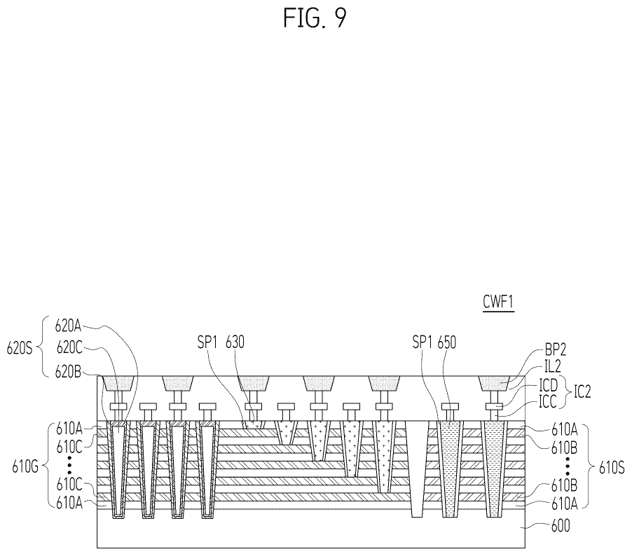

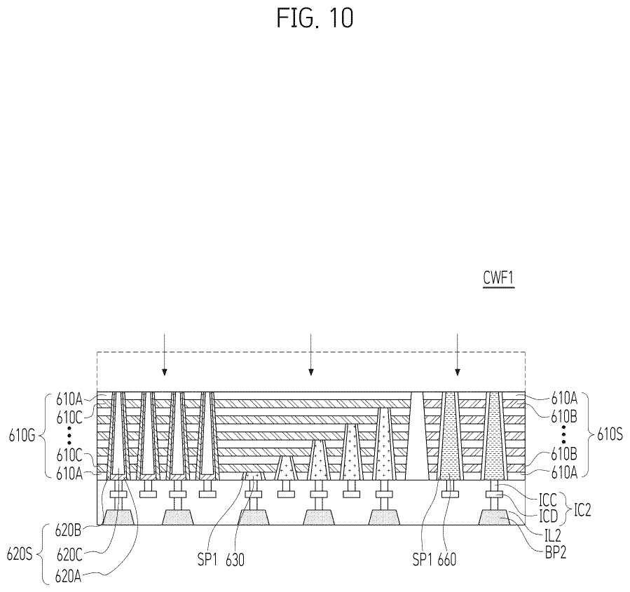

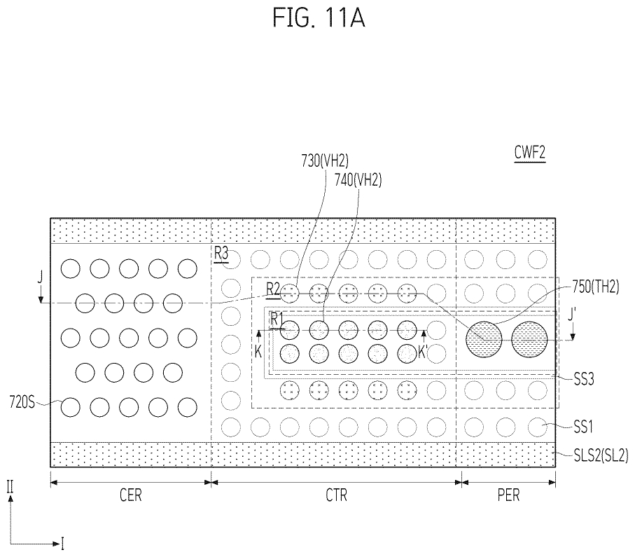

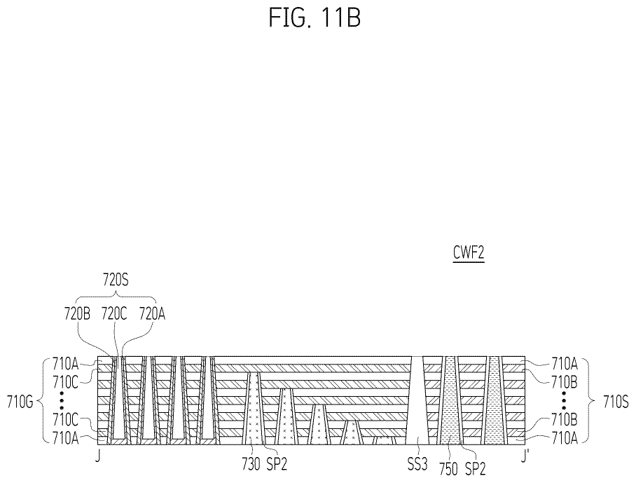

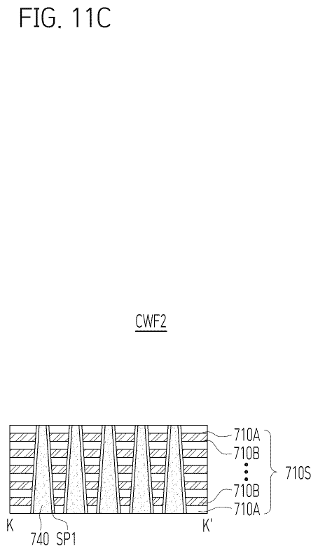

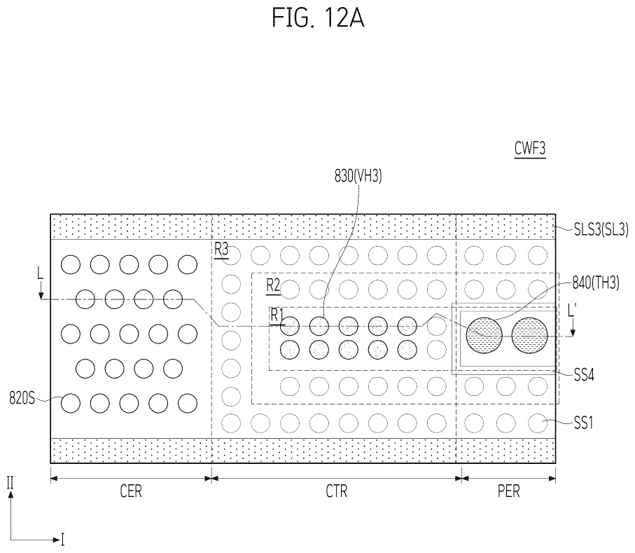

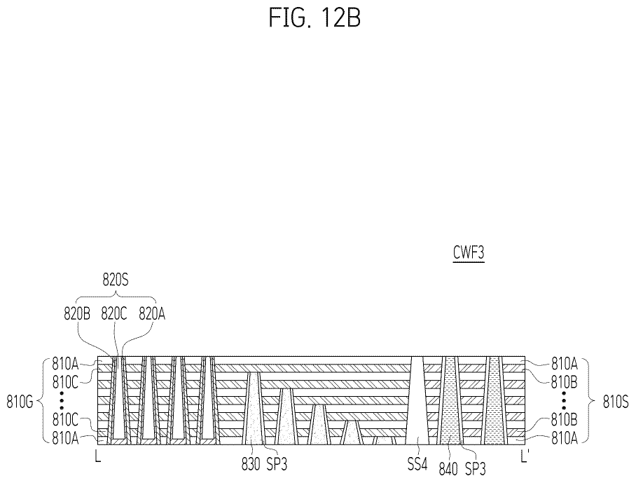

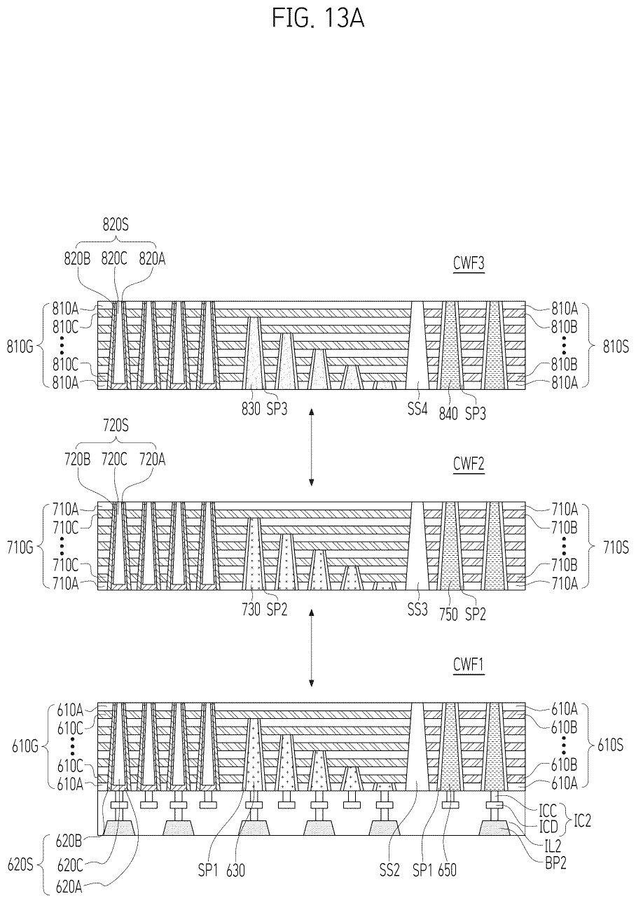

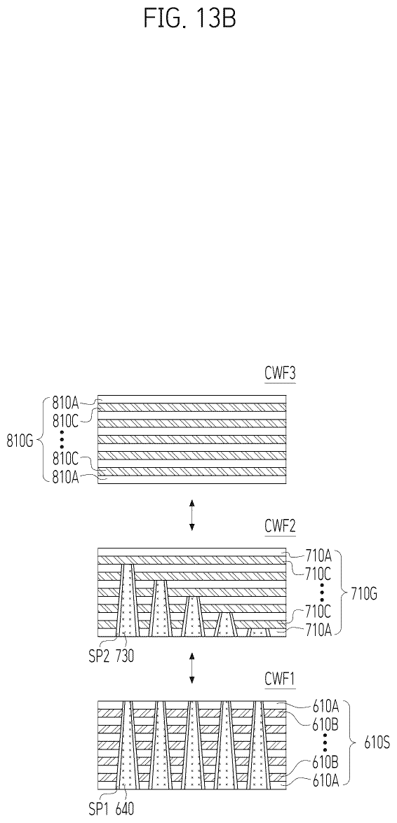

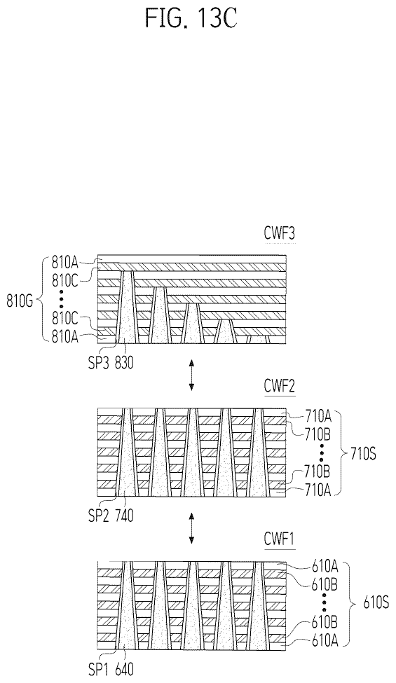

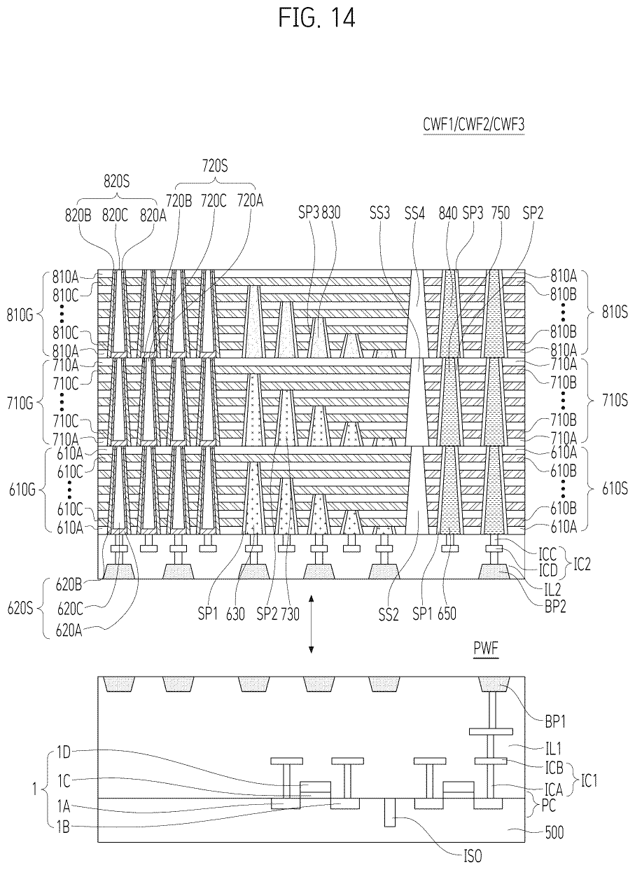

FIG. 5 is a cross-sectional view of a peripheral circuit wafer, FIG. 6A is a plan view of a first cell wafer, FIG. 6B is a cross-sectional view taken along line G-G′ of FIG. 6A, FIG. 7A is a plan view of the first cell wafer, FIG. 7B is a cross-sectional view taken along line G-G′ of FIG. 7A, FIG. 7C is a cross-sectional view taken along line H-H′ of FIG. 7A, FIG. 7D is a cross-sectional view taken along line I-I′ of FIG. 7A, FIG. 8A is a plan view of the first cell wafer, FIG. 8B is a cross-sectional view taken along line G-G′ of FIG. 8A, FIG. 8C is a cross-sectional view taken along line H-H′ of FIG. 8A, FIG. 8D is a cross-sectional view taken along line I-I′ of FIG. 8A, FIGS. 9 and 10 are cross-sectional views of the first cell wafer, FIG. 11A is a plan view of a second cell wafer, FIG. 11B is a cross-sectional view taken along line J-J′ of FIG. 11A, FIG. 11C is a cross-sectional view taken along line K-K′ of FIG. 11A, FIG. 12A is a plan view of a third cell wafer, FIG. 12B is a cross-sectional view taken along line L-L′ of FIG. 12A, FIGS. 13A to 13C are cross-sectional views of the first, second, and third cell wafers, and FIG. 14 is a cross-sectional view of the first, second, and third cell wafers and the peripheral circuit wafer. Hereinafter, content already described above is not repeated.

Referring to FIG. 5, the peripheral circuit wafer PWF may be formed. First, a peripheral circuit PC may be formed on a peripheral circuit substrate 500. Here, the peripheral circuit PC may be formed in a first interlayer insulating layer IL1. The first interlayer insulating layer IL1 may be formed on the substrate 500. The peripheral circuit PC may include a transistor 1. The transistor 1 may include junctions 1A and 1B, a gate electrode 1D, and a gate insulating layer 1C. Here, the gate insulating layer 1C may be formed between the gate electrode 1D and the peripheral circuit substrate 500. An element isolation layer ISO may be in the peripheral circuit substrate 500, an active region may be defined by the element isolation layer ISO, and the transistor 1 may be in the active region.

Subsequently, a first interconnection structure IC1 may be formed on the peripheral circuit PC. The first interconnection structure IC1 may include first vias ICA and first lines ICB. The first interconnection structure IC1 may be connected to the peripheral circuit PC. For example, at least one of the first vias ICA may be connected to the peripheral circuit PC.

FIGS. 6A and 6B, FIGS. 7A to 7D, FIGS. 8A to 8D, FIGS. 9 and 10 are drawings illustrating a method of manufacturing a first cell wafer CWF1.

Referring to FIGS. 6A and 6B, a first stack 610S may be formed over a first cell substrate 600. For example, the first stack 610S may be formed by alternately stacking first material layers 610A and second material layers 610B over the first cell substrate 600. Here, the first cell substrate 600 may include a cell region CER, a contact region CTR, and a peripheral circuit region PER. The first cell substrate 600 may include a first region R1, a second region R2 surrounding the first region R1, and a third region R3 surrounding the second region R2. The first material layers 610A may include an insulating material, such as an oxide, and the second material layers 610B may include a sacrificial material, such as a nitride. The second material layers 610B may be used as first sacrificial layers.

Subsequently, first sub-channel structures 620S extending through the first stack 610S may be formed. For example, the first sub-channel structures 620S extending into the first cell substrate 600 by passing through the first stack 610S may be formed. The first sub-channel structures 620S may include a first sub-channel layer 620A, a first sub-memory layer 620B surrounding the first sub-channel layer 620A, and a first sub-insulating core 620C in the first sub-channel layer 620A.

First supports SS1 and second support SS2 extending through the first stack 610S may be formed. The first supports SS1 may be in the contact region CTR and the peripheral circuit region PER. The second support SS2 may extend from the contact region CTR to the peripheral circuit region PER. The second support SS2 may define a region where the first stack 610S remains in the process of manufacturing the semiconductor device, and it may be formed to surround the first stack 610S. For example, the second support SS2 may be formed to surround the first stack 210S1 formed in the first and second regions R1 and R2. In this case, the first/second regions R1 and R2 and the third region R3 may be distinguished.

Referring to FIGS. 7A to 7D, first via holes VH1 extending into the first stack 610S may be formed. For example, the first via holes VH1 respectively exposing the second material layers 610B of the first stack 610S may be formed.

First through holes TH1 extending through the first stack 610S may be formed. For example, the first through holes TH1 extending into the first cell substrate 600 by passing through the first stack 610S may be formed.

Subsequently, a sacrificial material may be formed in the first via holes VH1 and the first through holes TH1. For example, the sacrificial material, such as tungsten, may be formed in the first via holes VH1 and the first through holes TH1. Alternatively, an insulating material, such as an oxide, may be formed in the first via holes VH1 and the first through holes TH1.

In FIGS. 8A to 8D, a first slit SL1 extending through the first stack 610S may be formed. Subsequently, at least one of the second material layers 610B of the first stack 610S may be replaced with a third material layer 610C through the first slit SL1. Accordingly, a first gate structure 610G including the first material layers 610A and the third material layers 610C alternately stacked may be formed. Here, the third material layers 610C may be gate lines such as source selection lines, word lines, and drain selection lines as a first conductive layer.

A portion of the first stack 610S may remain without being replaced with the first gate structure 610G. For example, the first stack 610S surrounded by the second support SS2 may remain without being replaced with the first gate structure 610G.

For reference, when the second material layers 610B include a conductive material, a process of replacing the second material layers 610B with the third material layers 610C may be omitted. In this case, the first stack 610S may be used as the first gate structure 610G.

Subsequently, a first slit structure SLS1 may be formed in the first slit SL1. The first slit structure SLS1 may include at least one of an insulating material, a conductive material, or a semiconductor material.

Subsequently, the sacrificial material formed in the first via holes VH1 and the first through holes TH1 may be removed. Subsequently, first insulating spacers SP1 including an insulating material, such as an oxide, may be formed in the first via holes VH1 and the first through holes TH1. Subsequently, additional holes respectively exposing the third material layers 610C may be formed in the first via holes VH1. Alternatively, additional holes exposing the first cell substrate 600 may be formed in the first through holes TH1. Subsequently, a conductive material, such as tungsten, may be formed in the additional holes. Accordingly, first contact vias 630 and first connection vias 640 may be formed in the first via holes VH1, and through plugs 650 may be formed in the first through holes TH1.

Alternatively, when an insulating material is formed in the first via holes VH1 and the first through holes TH1, additional holes passing through the insulating material may be formed. For example, additional holes respectively exposing the third material layers 610C may be formed. Alternatively, additional holes exposing the first cell substrate 600 may be formed. Subsequently, a conductive material, such as tungsten, may be formed in the additional holes. Accordingly, the first contact vias 630 and the first connection vias 640 may be formed in the first via holes VH1, and the through plugs 650 may be formed in the first through holes TH1. At this time, the insulating material formed in the first via holes VH1 and the first through holes TH1 may be used as first insulating spacers SP1.

Referring to FIG. 9, second bonding pads BP2 may be formed over the first gate structure 610G and the first stack 610S. The second bonding pads BP2 may be formed in a second interlayer insulating layer IL2. Here, the second interlayer insulating layer IL2 may be formed on the first gate structure 610G and the first stack 610S. The second interlayer insulating layer IL2 may include an insulating material, such as an oxide.

Before forming the second bonding pads BP2, a second interconnection structure IC2 may be formed in the second interlayer insulating layer IL2. The second interconnection structure IC2 may include second vias ICC and second lines ICD. The second interconnection structure IC2 may be, for example, above the first gate structure 610G and the first stack 610S and below the second bonding pads BP2.

Referring to FIG. 10, the first cell wafer CWF1 may be rotated. For example, after a carrier substrate or the like is bonded to the second bonding pads BP2, the first cell wafer CWF1 may be rotated. Subsequently, the carrier substrate may be removed. Subsequently, the first cell substrate 600 may be removed so that the first stack 610S or the first gate structure 610G is exposed. For example, the first cell substrate 600 may be planarized and removed so that the first stack 610S or the first gate structure 610G is exposed. Subsequently, the carrier substrate or the like may be bonded to the first stack 610S and the first gate structure 610G, and then the first cell wafer CWF1 may be rotated.

Referring to FIGS. 11A to 11C, a second cell wafer CWF2 may be formed. The second cell wafer CWF2 may be formed similarly to a method of forming the first cell wafer CWF1.

For example, a second stack 710S may be formed by alternately stacking fourth material layers 710A and fifth material layers 710B over a second cell substrate. Here, the second cell substrate may include a cell region CER, a contact region CTR, and a peripheral circuit region PER corresponding to the cell region CER, the contact region CTR, and the peripheral circuit region PER of the first cell substrate 600. The second cell substrate may include a first region R1, a second region R2, and a third region R3 corresponding to the first region R1, the second region R2, and the third region R3 of the first cell substrate 600. The fourth material layers 710A may include an insulating material, such as an oxide, and the fifth material layers 710B may include a sacrificial material, such as a nitride. The fifth material layers 710B may be used as second sacrificial layers.

Subsequently, second sub-channel structures 720S extending through the second stack 710S may be formed. The second sub-channel structures 720S may include a second sub-channel layer 720A, a second sub-memory layer 720B, and a second sub-insulating core 720C.

First supports SS1 and third support SS3 extending through the second stack 710S may be formed. The first supports SS1 may be in the contact region CTR and the peripheral circuit region PER. The third support SS3 may extend from the contact region CTR to the peripheral circuit region PER. The third support SS3 may be for defining a region where the second stack 710S remains in the process of manufacturing the semiconductor device, and it may be formed to surround the second stack 710S. For example, the third support SS3 may be formed to surround the second stack 710S formed in the first region R1. In this case, the first region R1 and the second/third regions R2 and R3 may be distinguished.

Subsequently, second via holes VH2 respectively exposing the fifth material layers 710B through the second stack 710S may be formed. Second through holes TH2 extending into the second cell substrate by passing through the second stack 710S may be formed. Subsequently, a sacrificial material may be formed in the second via holes VH2 and the second through holes TH2. Alternatively, an insulating material, such as an oxide, may be formed in the second via holes VH2 and the second through holes TH2.

Subsequently, a second slit SL2 extending through the second stack 710S may be formed. Subsequently, at least one of the fifth material layers 710B of the second stack 710S may be replaced with a sixth material layer 710C through the second slit SL2. Accordingly, a second gate structure 710G including the fourth material layers 710A and the sixth material layers 710C alternately stacked may be formed. Here, a portion of the second stack 710S may remain without being replaced with the second gate structure 710G. For example, the second stack 710S surrounded by the third support SS3 may remain without being replaced with the second gate structure 710G.

Subsequently, a second slit structure SLS2 may be formed in the second slit SL2. The second slit structure SLS2 may include at least one of an insulating material, a conductive material, or a semiconductor material.

Subsequently, second insulating spacers SP2, second contact vias 730, and second connection vias 740 may be formed in the second via holes VH2. The second insulating spacers SP2 and second through hole plugs 750 may be formed in the second through holes TH2.

Subsequently, after rotating the second cell wafer CWF2 using a carrier substrate or the like, the second cell wafer CWF2 may be planarized so that the second stack 710S or the second gate structure 710G is exposed, to remove the second cell substrate.

Referring to FIGS. 12A and 12B, a third cell wafer CWF3 may be formed. The third cell wafer CWF3 may be formed similarly to a method of forming the second cell wafer CWF2.

For example, a third stack 810S may be formed by alternately stacking seventh material layers 810A and eighth material layers 810B over a third cell substrate. Here, the third cell substrate may include a cell region CER, a contact region CTR, and a peripheral circuit region PER. The third cell substrate may include a first region R1, a second region R2, and a third region R3. The eighth material layers 810B may be used as third sacrificial layers.

Subsequently, third sub-channel structures 820S extending through the third stack 810S may be formed. The third sub-channel structures 820S may include a third sub-channel layer 820A, a third sub-memory layer 820B, and a third sub-insulating core 820C.

First supports SS1 and fourth support SS4 extending through the third stack 810S may be formed. The fourth support SS4 may define a region where the third stack 810S remains in the process of manufacturing the semiconductor device, and it may be formed to surround the third stack 810S formed in the first region R1. For example, the fourth support SS4 may be formed to surround the third stack 810S formed in the peripheral circuit region PER.

Subsequently, third via holes VH3 respectively exposing the fifth material layers 810B through the third stack 810S may be formed. Third through holes TH3 extending into the third cell substrate by passing through the third stack 810S may be formed. Subsequently, a sacrificial material may be formed in the third via holes VH3 and the third through holes TH3. Alternatively, an insulating material, such as an oxide, may be formed in the third via holes VH3 and the third through holes TH3.

Subsequently, a third slit SL3 extending through the third stack 810S may be formed. Subsequently, at least one of the eighth material layers 810B of the third stack 810S may be replaced with a ninth material layer 710C through the third slit SL3. Accordingly, a third gate structure 810G including the seventh material layers 810A and the ninth material layers 810C alternately stacked may be formed. Here, a portion of the third stack 810S may remain without being replaced with the third gate structure 810G. For example, the third stack 810S surrounded by the fourth support SS4 may remain without being replaced with the third gate structure 810G.

Subsequently, a third slit structure SLS3 may be formed in the third slit SL3. The third slit structure SLS3 may include at least one of an insulating material, a conductive material, or a semiconductor material.

Subsequently, third insulating spacers SP3 and third contact vias 730 may be formed in the third via holes VH3. The third insulating spacers SP3 and third through hole plugs 840 may be formed in the third through holes TH3.

Referring to FIGS. 13A to 13C, the first cell wafer CWF1 and the second cell wafer CWF2 may be bonded. For example, the first cell wafer CWF1 and the second cell wafer CWF2 may be bonded so that the first connection vias 640 of the first cell wafer CWF1 and the second connection vias 740 of the second cell wafer CWF2 are interconnected. In addition, the first cell wafer CWF1 and the second cell wafer CWF2 may be bonded so that the first connection vias 640 and the second contact vias 730 are interconnected. In addition, the first cell wafer CWF1 and the second cell wafer CWF2 may be bonded so that the first through plugs 650 and the second through plugs 750 are interconnected.

Subsequently, the second cell wafer CWF2 and the third cell wafer CWF3 may be bonded. For example, the second cell wafer CWF2 and the third cell wafer CWF3 may be bonded so that the second connection vias 740 of the second cell wafer CWF2 and the third contact vias 830 of the third cell wafer CWF3 are interconnected. Accordingly, the third contact vias 830 may be connected to the first connection vias 640 through the second connection vias 740.

In addition, the second cell wafer CWF2 and the third cell wafer CWF3 may be bonded so that the second through plugs 750 and the third through plugs 840 are interconnected. Accordingly, the third through plugs 840 may be connected to the first through plugs 650 through the second through plugs 750.

FIG. 14 is a drawing illustrating a method of bonding the peripheral circuit wafer and the first cell wafer.

Subsequently, the first cell wafer CWF1 and the peripheral circuit wafer PWF may be bonded. For example, the peripheral circuit wafer PWF and the first cell wafer CWF1 may be bonded so that the first bonding pads BP1 of the peripheral circuit wafer PWF and the second bonding pads BP2 of the first cell wafer CWF1 are interconnected.

Accordingly, the first, second, and third through plugs 650, 750, and 840 may be electrically connected to the peripheral circuit PC. For example, the first, second, and third through plugs 650, 750, and 840 may be electrically connected to the peripheral circuit PC through the second interconnection structure IC2, the first and second bonding pads BP1 and BP2, and the first interconnection structure IC1.

Although not shown in the drawing, before bonding the peripheral circuit wafer PWF and the first cell wafer CWF1, a source structure connected to the third sub-channel structures 820S may be formed. For example, the third sub-memory layer 820B may be removed to expose the third sub-channel layer 820A. Subsequently, the source structure connected to the third sub-channel layer 820A may be formed.

When forming a stack and/or gate structure of greater height on one cell wafer to improve the degree of integration of the semiconductor device, bending may occur in the stack and/or the gate structure in a manufacturing process. This problem may be aggravated when the height of the stack and/or the gate structure is increased. In addition, in a process of forming contact vias or through plugs extending through the stack, a problem in which via holes or through holes might not be formed at a desired depth may occur.

However, according to an embodiment of the present disclosure, the first, second, and third cell wafers CWF1, CWF2, and CWF3 and the peripheral circuit wafer PWF may be formed separately. In this case, heights of the first, second, and third gate structures 610G, 710G, and 810G and/or the first, second, and third stacks 610S, 710S, and 810S may be formed relatively small. Therefore, bending of the first, second, and third gate structures 610G, 710G, and 810G and/or the first, second, and third stacks 610S, 710S, and 810S may be prevented or reduced. In addition, the first, second, and third gate structures 610G, 710G, and 810G may be interconnected, a greater height of a semiconductor device may be achieved, and the degree of integration of the semiconductor device may be improved by interconnecting the first, second, and third stacks 610S, 710S, and 810S.

In addition, a height of the first, second, and third stacks 610S, 710S, and 810S may be formed relatively small, and in a process of forming the first/second/third through plugs 650, 750, and 840, the first/second/third through holes TH1, TH2, and TH3 may be formed by a desired depth to pass through the first/second/third stacks 610S, 710S, and 810S.

Although embodiments according to the technical spirit of the present disclosure have been described with reference to the accompanying drawings, the present disclosure is not limited to the above-described embodiments. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
a first gate structure including first conductive layers;
a first stack at a level corresponding to the first gate structure;
a second gate structure on the first gate structure and on the first stack, the second gate structure including second conductive layers;
a second stack at a level corresponding to the second gate structure;
a third gate structure on the second gate structure and on the second stack, the third gate structure including third conductive layers;
first contact vias extending into the first gate structure and respectively connected to the first conductive layers;
second contact vias passing through the first stack, extending into the second gate structure, and respectively connected to the second conductive layers; and
third contact vias passing through the first and second stacks, extending into the third gate structure, and respectively connected to the third conductive layers.

2. The semiconductor device of claim 1, further comprising:
a substrate under the first gate structure and under the first stack, the substrate including a first region extending in a first direction, a second region surrounding the first region, and a third region surrounding the second region.

3. The semiconductor device of claim 2, wherein the first stack is in the first region and in the second region, and
the second stack is in the first region.

4. The semiconductor device of claim 2, wherein the first gate structure is in the third region,
the second gate structure is in the second region and in the third region, and
the third gate structure is in the first region, in the second region, and in the third region.

5. The semiconductor device of claim 2, wherein the first contact vias are in the third region,
the second contact vias are in the second region, and
the third contact vias are in the first region.

6. The semiconductor device of claim 2, further comprising:
a peripheral circuit on the substrate;
a third stack in the first region and at a level corresponding to the third gate structure; and
a contact plug passing through the third stack, the second stack, and the first stack, the contact plug electrically connected to the peripheral circuit.

7. The semiconductor device of claim 6, further comprising:
a bonding structure between the peripheral circuit and the first gate structure and between the peripheral circuit and the first stack.

8. The semiconductor device of claim 6, further comprising:
first sub-channel structures extending through the first gate structure;
second sub-channel structures extending through the second gate structure and connected to the first sub-channel structures;
third sub-channel structures extending through the third gate structure and connected to the second sub-channel structures; and
a source structure on the third gate structure.

9. The semiconductor device of claim 8, wherein the source structure is connected to the third sub-channel structures.

10. A semiconductor device comprising:
a substrate including a first region, a second region surrounding the first region, and a third region surrounding the second region;
a first gate structure over the substrate in the third region, the first gate structure including first conductive layers;
a first stack in the first region and in the second region, the first stack at a level corresponding to the first gate structure;
a second gate structure on the first gate structure and on the first stack in the second region and in the third region, the second gate structure including second conductive layers;
a second stack in the first region at a level corresponding to the second gate structure;
a third gate structure on the second gate structure and on the third gate structure in the first region, in the second region, and in the third region, the third gate structure including third conductive layers;
first contact vias extending into the first gate structure in the third region and respectively connected to the first conductive layers;
second contact vias passing through the first stack in the second region and extending into the second gate structure, the second contact vias respectively connected to the second conductive layers; and
third contact vias passing through the first and second stacks in the first region and extending into the third gate structure, the third contact vias respectively connected to the third conductive layers.

11. The semiconductor device of claim 10, further comprising:
a peripheral circuit on the substrate;
a third stack in the first region and at a level corresponding to the third gate structure; and
a contact plug passing through the third stack, the second stack, and the first stack, the contact plug electrically connected to the peripheral circuit.

12. The semiconductor device of claim 11, further comprising:
a bonding structure between the peripheral circuit and the first gate structure and between the peripheral circuit and the first stack.

13. The semiconductor device of claim 11, further comprising:
first sub-channel structures extending through the first gate structure;
second sub-channel structures extending through the second gate structure and connected to the first sub-channel structures;
third sub-channel structures extending through the third gate structure and connected to the second sub-channel structures; and
a source structure on the third gate structure.

14. The semiconductor device of claim 13, wherein the source structure is connected to the third sub-channel structures.
